(19) United States
(12) Patent Application Publication
(10) Pub. No.: US 2012/0306076 A1
(43) Pub. Date: Dec. 6, 2012

(54) Semiconductor Micro-Connector With Through-Hole Via and a Method for Making the Same

(75) Inventor: Ying Hsu, San Clemente, CA (US)

(73) Assignee: ISC8 Inc., Costa Mesa, CA (US)

(21) Appl. No.: 13/479,585

(22) Filed: May 24, 2012

Related U.S. Application Data
(60) Provisional application No. 61/491,385, filed on May 31, 2011.

(51) Int. Cl. H01L 23/488; H01L 21/302

(52) U.S. Cl. 257/738; 438/700; 257/E21.214; 257/E23.023

(57) ABSTRACT

A micro-connector fabricated from a semiconductor material is disclosed. The micro-connector has one or more low resistance regions having a predetermined low resistance through its thickness. Opposing surfaces of the semiconductor layer have one or more complementary and opposing receiving volumes and one or more complementary mating elements defined on each of the respective surfaces within the low resistance regions for the receiving of a solder ball bond from, for instance a stackable microelectronic layer or component. The solder ball bonds of a separately provided electronic element can be inserted through the mating elements and into the volume and mechanically affixed and electrically coupled to the micro-connector on each of the surfaces for the electronic coupling of a first electronic element to a second electronic element.

### CROSS-REFERENCE TO RELATED APPLICATIONS

This application claims the benefit of U.S. Provisional Patent Application No. 61/491,385, filed on May 31, 2011, entitled “Micro-Connector for Stackable Layers” pursuant to 35 USC 119, which application is incorporated fully herein by reference.

### STATEMENT REGARDING FEDERALLY SPONSORED RESEARCH AND DEVELOPMENT

N/A

### BACKGROUND OF THE INVENTION

1. Field of the Invention

The invention relates generally to the field of electronics and electronic coupling devices. More specifically, the invention relates to a micro-connector assembly with one or more semiconductor through-hole vias that is fabricated from a semiconductor layer for use with bare die, stackable microelectronic layers and modules, focal plane arrays and other suitable electronic devices and assemblies.

2. Description of the Related Art

The ability to fabricate very thin, stackable layers containing one or a plurality of bare or modified homogeneous or heterogeneous integrated circuit chips is desirable and allows high-density, high-speed electronic systems to be assembled for use in military, space, security and other applications.

Examples of such layers and modules are disclosed in U.S. Pat. No. 6,072,234, entitled Stack of Equal Layer Neo-Chips Containing Encapsulated IC Chips of Different Sizes, U.S. Pat. No. 6,797,537, entitled Method of Making Stackable Layers Containing Encapsulated Integrated Circuit Chips With One or More Overlying Interconnect Layers, U.S. Pat. No. 6,784,547, entitled Stackable Layers Containing Encapsulated Integrated Circuit Chips With One or More Overlying Interconnect Layers, U.S. Pat. No. 6,117,704, entitled Stackable Layer Containing Encapsulated Chips, U.S. Pat. No. 6,072,234, entitled Stack of Equal Layer Neo-Chips Containing Encapsulated IC Chips of Different Sizes, U.S. Pat. No. 5,953,588, entitled Stackable Layers Containing Encapsulated IC Chips, and U.S. Pat. No. 7,768,113, entitled Stackable Tier Structure Comprising Prefabricated High Density Feed-through.

The stacking and interconnection of very thin microelectronic layers permits high circuit speeds in part because of short lead lengths with related reduced parasitic impedance and reduced electron time-of-flight. These desirable features combined with a very high number of circuit and layer interconnections allow relatively large I/O designs to be implemented in a small volume.

A prior art example of stackable layers is the use of a “neo-chip” or “neo-layer” involving the “potting” of individual IC chips in a encapsulant which supports and insulates each chip and which can be cut or diced to provide equal area layers, so that chips having different sizes can be stacked in layers.

A further example of the prior art use of stackable layers in microelectronic modules involves certain LIDAR processing modules wherein a stack of readout integrated circuit chips (“ROIC”s) are stacked in a module and wherein a focal plane array is bonded and electrically coupled to a lateral surface of the stack.

Other prior art electrical coupling methods for stackable layers and modules include the use of “fuzz buttons”, indium or solder bump-bonding, thermo-sonic coupling and the use of conductive epoxies. A focal plane array assembly coupling method incorporating fuzz buttons is disclosed in, for instance, U.S. Pat. No. 7,436,494, entitled “Three-Dimensional LADAR Module with Alignment Reference Insert Circuitry” to Kennedy et al.

A yet further example of a prior art use of stackable layers in microelectronic modules is the electronic coupling of a plurality of bare IC die in focal plane array assemblies comprising a stack of ROICs in a “stack of pancakes” or horizontal format, as is found in buttable focal plane array mosaic structures used for providing very high pixel count imaging.

In the prior art FPA mosaic and LIDAR imaging modules above and because of the very high cost of the elements in the layers in the related stacks, reworkability and the ability to easily replace an individual focal plane array element in the event of a failure is very desirable.

A deficiency in the use of the above prior art stackable microelectronic layer applications is the complex assembly process associated with bonding and electrically coupling the layers during electronic module fabrication. The multi-step bonding, baking, photolithography and plating processes are costly, slow and can result in yields that are lower than desirable.

Further compounding the above deficiencies is that in the event a single layer fails during fabrication of a stacked module, (which can exceed 100 individual layers), the module cannot practically be reworked and must be scrapped.

What is needed is a simple, low-cost and reliable device that can be used to electrically couple an electronic element, component or assembly to another electronic element, component or assembly or to any external circuitry and that permits the coupled elements to be easily removed and replaced or reworked. Further, what is needed is a device that is low-profile and that can accommodate the physical performance concerns (such as well-matched coefficient of thermal expansion and operating temperature range) that are present in the operation and environment of an electronic circuit.

### BRIEF SUMMARY OF THE INVENTION

A micro-connector fabricated from a semiconductor material is disclosed. The micro-connector has one or more conductive regions having a predetermined conductivity through its thickness. Opposing surfaces of the semiconductor layer have one or more complementary and opposing receiving volumes and one or more complementary mating elements defined on each of the respective surfaces within the conductive regions for the receiving of a solder ball bond from, for instance, a stackable microelectronic layer, focal plane array or component. The solder ball bonds of a separately provided electronic element or layer can be inserted into the volume and mechanically affixed and electrically coupled to the micro-connector on each of its opposing surfaces for the electronic coupling of a first electronic element to a second electronic element.

While the claimed apparatus and method herein has or will be described for the sake of grammatical fluidity with functional explanations, it is to be understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112, are to be accorded full statutory equivalents under 35 USC 112.

### BRIEF DESCRIPTION OF THE SEVERAL VIEWS OF THE DRAWINGS

FIG. 1 is a cross-section of the micro-connector of the invention electrically coupling two stackable microelectronic layers each having solder ball bonds electrically coupled to the pads of the layers.

FIG. 2 is a top view of the first surface of FIG. 1 illustrating a preferred embodiment of the first receiving volume and mating elements for receiving and electrically coupling a solder ball bond on an electronic element.

FIGS. 3-8 illustrate a preferred method for making the micro-connector of the invention.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE INVENTION

Turning now to the figures wherein like numerals denote like elements among the several views, a micro-connector and method for making same is disclosed.

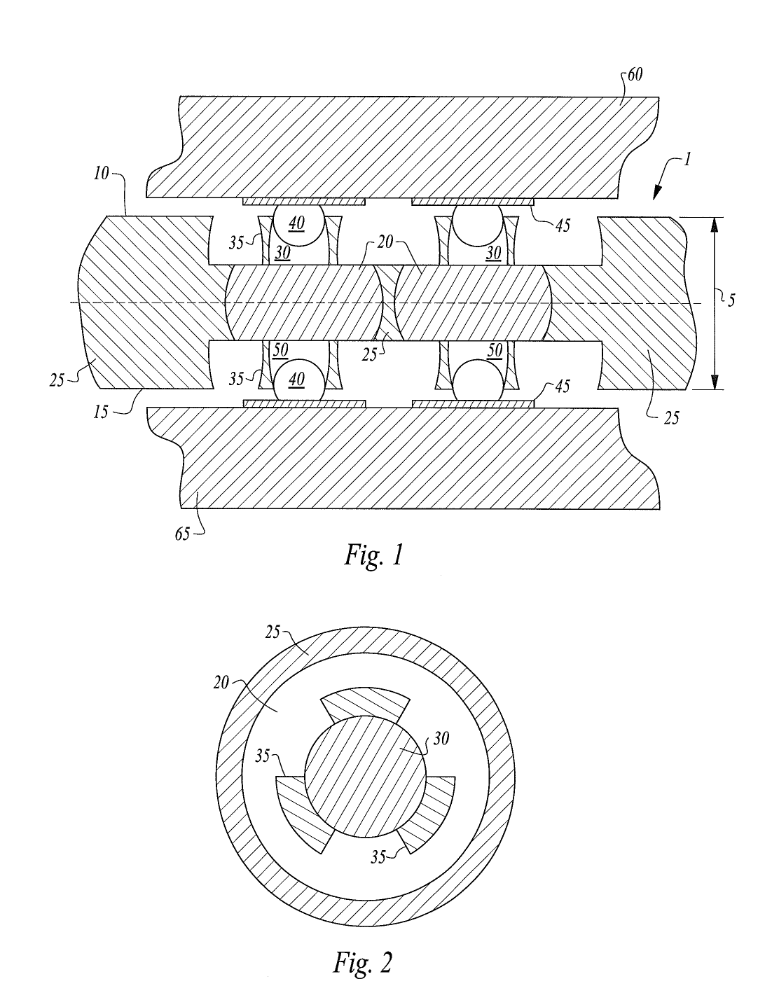

As depicted in FIG. 1, Applicant discloses a semiconductor micro-connector for use with an electronic element or elements which may, in an exemplar application, comprise one or more stackable layers comprising integrated circuitry such as for use in applications with an IR focal plane array or where the focal plane array module comprises a stackable layer.

The invention is desirably fabricated using well-known semiconductor etching (i.e., MEMS) processes resulting in very fine pitch connectors which can be less than about 100 microns.

The invention generally comprises a monolithic semiconductor interconnected tier or layer micro-connector structure that comprises one or more mating elements and volumes for receiving one or more conductive elements, solder balls, bumps or stud bumps on one or more electronic devices.

The invention comprises one or more micro-etched “beams” in the form of mating elements defined on doped areas of the layer of relatively high electrical conductivity.

The mating elements and volumes of the invention are fabricated using known semiconductor processes; preferably processes suitable for fabricating high aspect ratio structures, e.g., deep reactive ion etching or DRIE, processes.

Turning now to the figures wherein like numerals denote like elements among the several views, a micro-connector, a method for making a micro-connector and a micro-connector made from the process are disclosed.

FIGS. 1 and 2 depict a preferred embodiment of the micro-connector 1 of the invention.

Micro-connector 1 is fabricated from a semiconductor material such as silicon or germanium but may be fabricated from any semiconductor material having suitable thermal, electrical and doping properties for the desired end application.

Micro-connector layer 1 comprises a thickness 5, a first surface 10 and a second surface 15.

Micro-connector 1 is provided with at least one electrically conductive region 20 defined through thickness 5 having a predefined low electrical resistance region there through. In a preferred embodiment, the low resistance regions have a resistance of about 0.002 to about 0.05 ohms-cm.

Micro-connector 1 further comprises at least one insulative boundary 25 having a predefined high electrical resistance defined through thickness 5 and encompassing low resistance region 20. In a preferred embodiment, the predefined high resistivity is greater than about 10,000 ohms-cm.

A first receiving volume 30 and one or a plurality of mating elements 35 are defined in the semiconductor material comprising low resistance region 20 on first surface 10.

First receiving volume 30 and one or more mating elements 35 are configured to receive and be in electrical communication with a conductive element 40.

Conductive element 40 may comprise a solder ball or conductive metal stud bump fabricated from a wire bonder that is disposed on a conductive pad 45 of a separately provided electrical component, circuit element, printed circuit board, stackable layer, focal plane array or equivalent electronic assembly.

In an alternative preferred embodiment, micro-connector 1 further comprises one or a set of complementary and opposing second receiving volumes 50 and one or a plurality of mating elements 35 defined on the second surface 15.

The second receiving volumes 50 and related mating elements 35 are defined in the same low resistance region 20, and are bounded by the same insulative boundary 25, as the complementary and opposing first receiving volume 30 and related mating elements 35 on the opposing first surface 10.

Insulative region 25 is preferably fabricated of an oxide material such as silicon dioxide or aluminum nitride or equivalent dielectric material deposited in a chemical vapor deposition process or low-pressure chemical vapor deposition process as is known in the semiconductor fabrication arts.

Low resistance region 20 is preferably defined using well-known semiconductor doping processes so as to provide less than about one ohm of resistance between the opposing and complementary mating elements 35 defined on the first surface 10 and second surface 15.

As is depicted in in the exemplar embodiment of FIGS. 1 and 2, first stackable layer 60 or second stackable layer 65 or both, comprising one or more conductive elements 40 such as solder balls, are conveniently electrically coupled to each other by inserting the respective conductive elements 40 through the mating elements 35 and into the respective first and second receiving volumes 30 and 50 whereby the respective electrically conductive mating elements 35 flex upon insertion of conductive elements 40 and then grip, hold and are electrically coupled thereto.

In this manner, low resistance region 20 functions as an insulated, electrical through-hole via in micro-connector 1 to provide a low-cost, low-profile micro-connector 1 for stackable layers or integrated circuit chips.

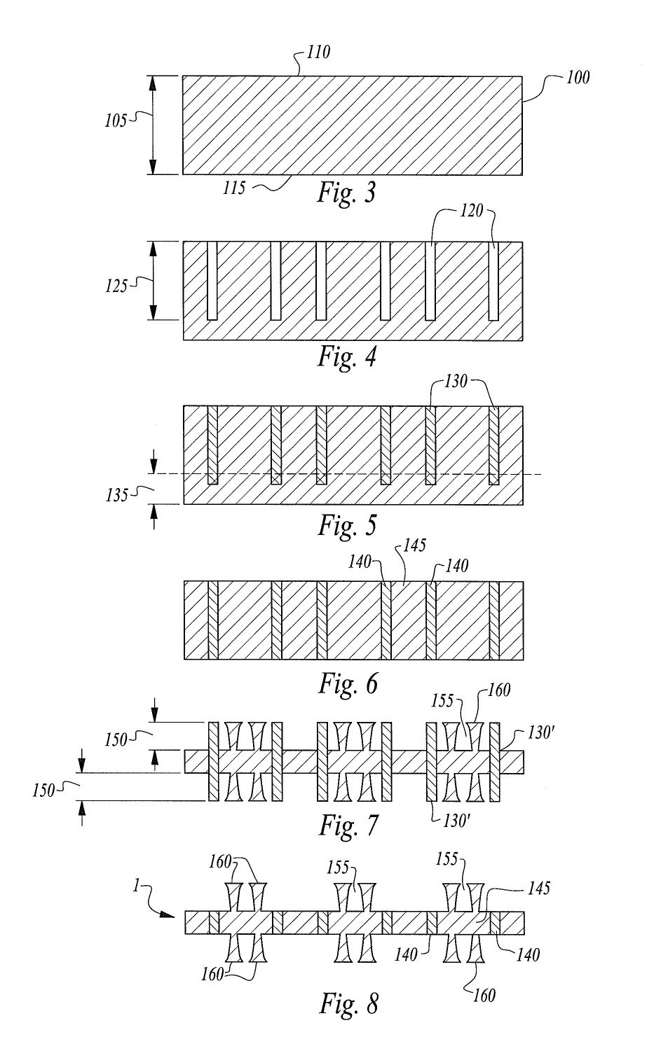

In a further aspect of the invention, a method for making a micro-connector and a device made from the method is disclosed in FIGS. 3 through 8.

Turning to FIG. 3, the method comprises the step of providing a semiconductor micro-connector layer 100 comprising a thickness 105, a first surface 110 and a second surface 115 and has a predefined electrical conductivity, preferably comprising a high conductivity, i.e., low resistance silicon material with a resistivity of about 0.002 to about 0.05 ohm-cm.

Turning to FIG. 4, one or more isolation trenches 120 are defined on first surface 110 having a predetermined depth 125 using, for instance, a deep reactive ion etching process or equivalent etching means suitable to define the desired isolation trench geometry.

As depicted in FIG. 5, isolation trenches 120 are filled with a dielectric, insulative material 130 such as with an oxide; for instance silicon dioxide or aluminum nitride, using known semiconductor processes. Exemplar semiconductor processes for providing the dielectric within the isolation trench volume include, by way of example and not by limitation, using a chemical vapor deposition or low-pressure chemical vapor deposition process or equivalent semiconductor deposition or dielectric growth means.

With respect to FIGS. 5 and 6, a first predetermined thickness portion 135 of second surface 115 is removed using known grinding, polishing or CMP processes to expose a portion of dielectric material 130 on first surface 110 and second surface 115 and to define an insulative boundary 140 encompassing a low resistance region 145.

Turning to FIG. 7, a second predetermined portion 150 of first surface 110 or second surface 115 or both is removed in a first etching process to expose a portion of the dielectric material 130′ and to define a receiving volume 155 and one or more mating elements 160 in a first etching process.

As illustrated in FIG. 8, the exposed portion of dielectric material 130′ is removed in a second etching process to provide a semiconductor micro-connector 1 with well-matched CTE to coupled electronic devices and layers and that permits the removal and replacement of a stackable layer, focal plane array assembly or buttable focal plane array mosaic structure. The micro-connector device of the invention beneficially requires only a low insertion force to insert a stackable layer. The “wiping” action of the mating elements during insertion beneficially breaks any surface oxide on the metallic bumps or conductive elements of the stackable layers.

The invention permits the fabrication of large arrays with small pitches. The built-in layer-to-layer alignment and contact reference features are desirable for small features typical of microelectronics. The limitation is actually in the size of the metallic balls on the stackable layers.

The compliance of the mating elements desirably accommodates lateral movement of the assembled devices such as due to the coefficient of thermal expansion (“CTE”) differences between the assembled or interconnected elements.

Multiple mating elements in the micro-connector may also be provided to insure redundant and reliable electrical contacts.

The stackable layers can be under-filled with a suitable epoxy to permanently lock the connections after testing or a removable layer-to-layer adhesive applied on a lateral surface of a stacked assembly to “lock” the layers into place.

In one application of the micro-connector, the invention functions as an electrical interface between the detector cells in a focal plane array or “FPA” to a large multiplexer chip.

Alternatively, a user may etch the micro-connector onto the CMOS chip. In such an application, each micro-connector may connect a 512×512 FPA detector array to form an 8K×8K detector.

In yet a further application, the micro-connector of the invention may be beneficially incorporated into a mosaic buttable focal plane array assembly such as is disclosed in FIGS. 7a, 7b and 8 in U.S. Pat. No. 7,335,576, entitled Method for Precision Integrated Circuit Die Singulation Using Differential Etch Rates to permit the simple removal and replacement of a focal plane array tile in a mosaic of focal plane array tiles.

Using known design principles, the micro-connector is strong enough to hold a detector and withstand a launch environment without the need for an external clamp or adhesive, yet the connection can still be separated by force to permit removal of the detector from a stack.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims For example, notwithstanding the fact that the elements of a claim are set forth below in a certain combination, it must be expressly understood that the invention includes other combinations of fewer, more or different elements, which are disclosed in above even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention.

I claim:

1. A micro-connector comprising:
a semiconductor micro-connector layer comprising a thickness, a first surface and a second surface,
at least one low resistance region defined through the thickness having a predefined low electrical resistance,
at least one insulative boundary having a predefined high electrical resistance defined through the thickness and encompassing the low resistance region, and,
a first receiving volume and at least one mating element defined in the low resistance region on the first surface and configured to receive a conductive element.

2. The micro-connector of claim 1 further comprising a complementary and opposing second receiving volume and at least one mating element defined on the second surface within the same low resistance region and bounded by the same insulative boundary as the opposing first receiving volume.

3. The micro-connector of claim 1 wherein the conductive element is a solder ball.

4. The micro-connector of claim 1 wherein the conductive element comprises at least one stud bump.

5. The micro-connector of claim 1 wherein the predefined low resistance is about 0.002 to about 0.05 ohms-cm.

6. The micro-connector of claim 1 wherein the predefined high resistance is greater than about 10,000 ohms-cm.

7. The micro-connector of claim 1 wherein the insulative region is comprised of an oxide material deposited in a chemical vapor deposition process.

8. The micro-connector of claim 1 wherein the insulative region is comprised of an oxide material deposited in a low pressure chemical vapor deposition process.

9. The micro-connector of claim 1 wherein the semiconductor micro-connector layer is comprised of a silicon semiconductor material

10. The micro-connector of claim 1 wherein the semiconductor micro-connector layer is comprised of a germanium semiconductor material.

11. The micro-connector of claim 1 wherein the low resistance region is defined using a semiconductor doping process.

12. The micro-connector of claim 2 wherein the resistance between the mating element defined on the first surface and the complementary and opposing mating element defined on the second surface is less than about one ohm.

13. A method for making a micro-connector comprising the steps of:
providing a semiconductor micro-connector layer comprising a thickness, a first surface and a second surface and having a predefined electrical conductivity,
defining an isolation trench on the first surface having a predetermined depth,
filling the isolation trench with a dielectric material,
removing a predetermined portion of the second surface to expose the dielectric material to define an insulative boundary encompassing a low resistance region,
removing a predetermined portion of the first surface to expose a portion of the dielectric material and to define a receiving volume and a mating element in a first etching process, and,
removing the exposed portion of the dielectric material in a second etching process.

14. A micro-connector made from a process comprising the steps of:
providing a semiconductor micro-connector layer comprising a thickness, a first surface and a second surface and having a predefined electrical conductivity,
defining an isolation trench on the first surface having a predetermined depth,
filling the isolation trench with a dielectric material,
removing a predetermined portion of the second surface to expose the dielectric material to define an insulative boundary encompassing a low resistance region,
removing a predetermined portion of the first surface to expose a portion of the dielectric material and to define a receiving volume and a mating element in a first etching process, and,
removing the exposed portion of the dielectric material in a second etching process.
